(19) United States
(12) Patent Application Publication
(10) Pub. No.: US 2014/0131081 A1
(43) Pub. Date: May 15, 2014

(54) PRINTED CIRCUIT BOARD AND METHOD OF MANUFACTURING THE SAME

(71) Applicant: SAMSUNG ELECTRO-MECHANICS CO., LTD., Suwon (KR)

(72) Inventors: Hye Jin Cho, Suwon (KR); Se Kyung Lee, Suwon (KR); Bae Soon Son, Suwon (KR); Suk Jin Ham, Suwon (KR)

(73) Assignee: SAMSUNG ELECTRO-MECHANICS CO., LTD., Suwon (KR)

(21) Appl. No.: 13/827,656

(22) Filed: Mar. 14, 2013

(30) Foreign Application Priority Data
Nov. 9, 2012 (KR) 10-2012-0126812

(51) Int. Cl. H05K 3/20

(52) U.S. Cl. CPC H05K 3/207
USPC 174/258; 174/261; 427/98.4; 427/558

(57) ABSTRACT

Disclosed herein is a printed circuit board, including: a base substrate on which a connection pad is formed; a dam spaced apart from one side of the connection pad; and a protective layer formed to surround the dam.

### CROSS REFERENCE TO RELATED APPLICATION

This application claims the benefit of Korean Patent Application No. 10-2012-0126812, filed on Nov. 9, 2012, entitled “Printed Circuit Board and Method of Manufacturing the Same,” which is hereby incorporated by reference in its entirety into this application.

### BACKGROUND OF THE INVENTION

1. Technical Field

The present invention relates to a printed circuit board and a method of manufacturing the same.

2. Description of the Related Art

With the recent development of a semiconductor technology, a demand for a highly integrated and multi-functional semiconductor package has increased. Therefore, at least one semiconductor chip, such as a capacitor, a register, and the like, needs to be mounted on a board on which semiconductor chips are mounted. For the miniaturization of a product, the use of a product of a flip chip package (FCCSP) as a printed circuit board on which semiconductor chips are mounted has suddenly increased. At the time of forming the package, an underfill resin is injected into a space between the board and the semiconductor chip. The underfill resin has the increased flowability due to a heating process after being injected, and the like, such that the underfill resin may be discharged to an outside of the space between the semiconductor chip and the substrate. To prevent this, a dam is formed. Generally, the dam may be formed by attaching a solder resist film on an upper portion of the substrate and then, patterning the solder resist film so that the solder resist film remains only in an area in which the dam is formed. Alternatively, the dam may be formed by applying and hardening a dam ink, that is, a liquid-phase solder resist only to the area in which the dam is formed (U.S. Pat. No. 6,391,682). However, when forming the dam using the solder resist film, the solder resist film is applied over the substrate and is patterned, such that the number of processes and costs are increased. Further, when forming the dam using the dam ink, the dam ink is not sufficiently hardened, another process is performed later, such that the structure of the dam may be collapsed.

### SUMMARY OF THE INVENTION

The present invention has been made in an effort to provide a printed circuit board capable of forming a dam with improved hardness using an inkjet type and a method of manufacturing a printed circuit board.

Further, the present invention has been made in an effort to provide a printed circuit board capable of saving time and costs by optionally forming a dam and a method of manufacturing a printed circuit board.

According to a preferred embodiment of the present invention, there is provided a printed circuit board, including: a base substrate on which a connection pad is formed; a dam spaced apart from one side of the connection pad; and a protective layer formed to surround the dam.

The dam may be formed of solder resist.

The protective layer may be formed of liquid-phase thermoplastic resin.

The protective layer may be formed of liquid-phase polyethylene terephthalate.

At least one connection pad may be formed.

The dams may be consecutively formed so as to be spaced apart from each other along one side of at least one connection pad.

According to another preferred embodiment of the present invention, there is provided a method of manufacturing a printed circuit board, including: preparing a base substrate on which a connection pad is formed; forming temporarily hardened dams spaced apart from one side of the connection pad; forming a protective layer surrounding the dams; and hardening the temporarily hardened dams.

The forming of the temporarily hardened dam may include: applying dam ink to a position at which the dam is spaced apart from one side of the connection pad; and temporarily hardening the dam ink

The dam ink may be a liquid-phase photo resist.

The temporarily hardening of the dam ink may be performed by irradiating ultraviolet rays to the applied dam ink.

In the forming of the protective layer, the liquid-phase protective layer may be applied to surround the dam.

The protective layer may be formed of a liquid-phase thermoplastic resin.

The protective layer may be formed of liquid-phase polyethylene terephthalate.

The hardening of the temporarily hardened dams may include performing first hardening that irradiates ultraviolet rays to the temporarily hardened dams; and performing second hardening that heats the dams hardened by ultraviolet rays.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram illustrating a printed circuit board according to a preferred embodiment of the present invention;

FIGS. 2 to 5 are a diagram illustrating a method of manufacturing a printed circuit board according to the preferred embodiment of the present invention;

FIG. 6 is a diagram illustrating an existing dam; and

FIG. 7 is a diagram illustrating a dam according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

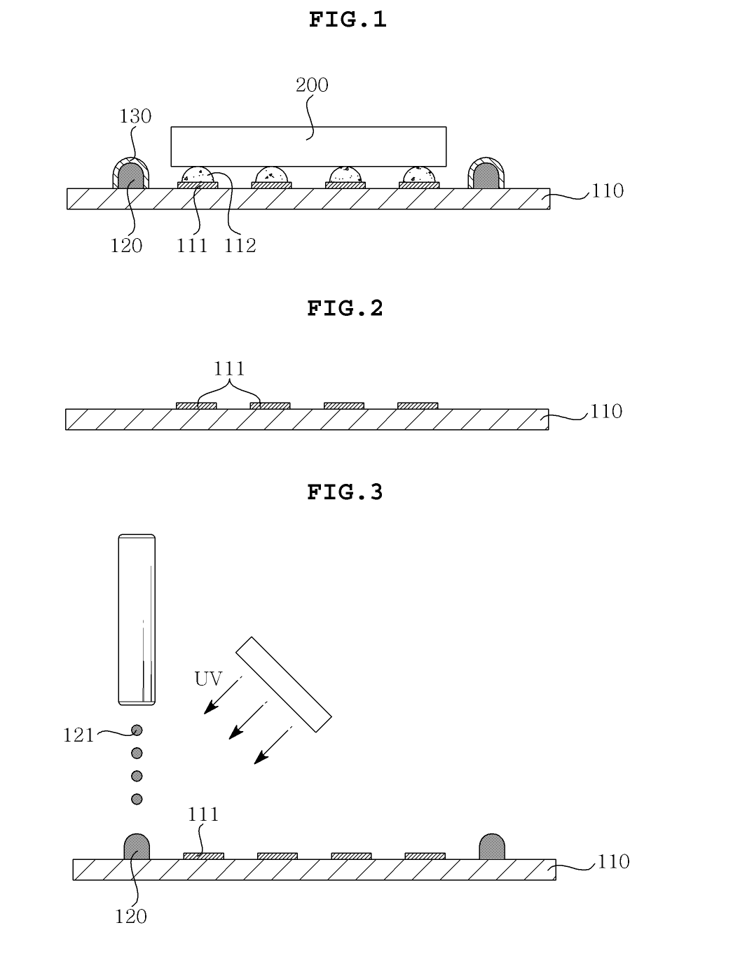

FIG. 1 is a diagram illustrating a printed circuit board according to a preferred embodiment of the present invention.

Referring to FIG. 1, a printed circuit board 100 may include a base substrate 110, a dam 120, and a protective layer 130.

The base substrate 110 may be a substrate on which an electronic component 200 such as a semiconductor chip, and the like, is mounted later. The base substrate 110 may be formed with a circuit layer including a connection pad 111. The connection pad 111 may be a component electrically connected with the electronic component 200. A preferred embodiment of the present invention illustrates that the connection pad 111 is formed on the base substrate, but is not limited thereto. The connection pad 111 may be formed on or beneath the base substrate 110. Further, at least one connection pad 111 may be formed. A bump 112 may be formed on the connection pad 111. Further, the electronic component 200 is mounted on the bump 112, such that the electronic component 200 may be mounted on the base substrate 110. Further, although not illustrated in FIG. 1, the base substrate 110 may be further formed with a solder resist layer (not illustrated) that is formed with an opening exposing the connection pad 111.

The dam 120 may be spaced apart from one side of the connection pad 111. The dam 120 may prevent an underfill solution from being leaked to the outside when the electronic component 200 is mounted on the base substrate 110 and the underfill solution is injected between the base substrate 110 and the electronic component 200. The dam 120 may be formed of a solder resist. In more detail, the dam 120 may be formed by applying and hardening a liquid-phase solder resist.

The dams 120 may be consecutively formed while being spaced apart from each other along one side of at least one connection pad 111 formed on the base substrate 110. That is, the dam 120 may be formed to surround all the plurality of connection pads 111. For example, when the electronic component 200 is mounted on the base substrate 110, the dam 120 may be formed between an outer edge of the electronic component 200 and an outer edge of the base substrate 110.

The protective layer 130 may be formed to surround the upper portion of the dam 120. The protective layer 130 may prevent the dam 120 from being non-hardened due to the reaction of the liquid-phase dam 120 with oxygen in the air at the time of hardening the liquid-phase dam 120. The protective 130 may be formed of liquid-phase thermoplastic resin. For example, the protective layer 130 may be formed of liquid-phase polyethylene terephthalate (PET).

According to the preferred embodiment of the present invention, in order to prevent the underfill solution from being leaked to the outside, a height of the dam 120 or the height of the dam 120 and the protective layer 130 may be formed to be higher than a space height between the base substrate 110 and the electronic component 200.

According to the printed circuit board of the preferred embodiment of the present invention, the protective layer is formed to surround the dam, thereby improving the hardness of the liquid-phase dam. Further, a freedom in design for the formation of the dam according to the use of the liquid-phase dam may be improved due to the improvement of hardness. Further, the dam is formed only at a position at which the dam needs to be formed, thereby more saving the time and costs than the case of using the film type dam.

FIGS. 2 to 5 are a diagram illustrating a method of manufacturing a printed circuit board according to the preferred embodiment of the present invention.

Referring to FIG. 2, the base substrate 110 on which the connection pad 111 is formed maybe prepared.

The base substrate 110 may be a substrate on which an electronic component 200 such as a semiconductor chip, and the like, is mounted later. The base substrate 110 may be formed with the connection pad 111 as well as a circuit layer such as a via, a circuit pattern, and the like. The connection pad 111 may be a component electrically connected with the electronic component 200. A preferred embodiment of the present invention illustrates that the connection pad 111 is formed on the base substrate, but is not limited thereto. The connection pad 111 may be formed on or beneath the base substrate 110. Further, at least one connection pad 111 may be formed. Further, although not illustrated in FIG. 3, the base substrate 110 may be further formed with a solder resist layer (not illustrated) that is formed with an opening exposing the connection pad 111.

Referring to FIG. 3, a temporarily hardened dam 120 may be formed on the base substrate 110. First, the dam ink 121 may be applied on the base substrate 110 by the inkjet type. The dam ink 121 may be a liquid-phase photo resist. The dam ink 122 may be applied at a position that is spaced apart from one side of the connection pad 111. Further, the dam ink 121 may be consecutively applied while being spaced apart from each other along one side of at least one connection pad 111 formed on the base substrate 110. That is, the dam ink 121 may be formed to surround all the plurality of connection pads 111. For example, the dam ink 121 may be applied between the outer edge of at least one connection pad 111 and the outer edge of the base substrate 110.

As described above, the dam ink 121 applied on the base substrate 110 may be temporarily hardened. In this case, the dam ink 121 may be temporarily hardened by being irradiated with ultraviolet rays. The temporary hardening of the dam 120 may be performed by applying the dam ink 121 on the base substrate 110. Alternatively, the temporary hardening of the dam 120 may be performed while applying the dam ink 121 on the base substrate 110.

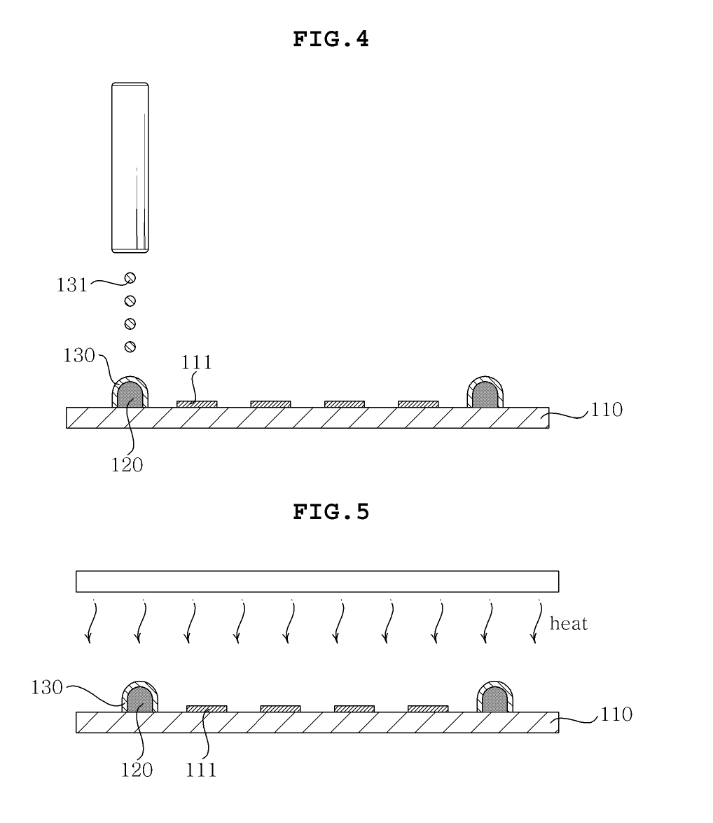

Referring to FIG. 4, the protective layer 130 may be formed on the temporarily hardened dam 120. The protective layer 130 may be formed to surround the temporarily hardened dam 120 in a liquid-phase form. The protective 130 may be formed of liquid-phase thermoplastic resin 131. The protective layer 130 is made in a liquid-phase form by heating the thermoplastic resin, which may be in turn applied on the temporarily hardened dam 120. For example, the protective layer 130 may be formed of liquid-phase polyethylene terephthalate (PET). The protective layer 130 may prevent the dam 120 from being non-hardened due to the reaction with oxygen in the air when the temporarily hardened dam 120 is completely hardened.

The height of the dam 120 or the height of the dam 120 and the protective layer 130, which are illustrated in FIGS. 3 and 4, may be formed to be higher than that of the space between the electronic component (not illustrated) mounted on the base substrate 110 and the base substrate 110. By the above formation, when the underfill solution is injected into the space between the base substrate 110 and the electronic component (not illustrated) later, it is possible to prevent the underfill solution from being leaked to the outside by the dam 120 and the protective layer 130.

Referring to FIG. 5, the temporarily hardened dam 120 may be hardened. The dam 120 may be completely hardened by supplying heat to the temporarily hardened dam 120 surrounded with the protective layer 130. First, first hardening that is a post bake that irradiates ultraviolet rays to the temporarily hardened dam 120 may be performed. The first hardening that is the post bake is performed and then, the second hardening that is a complete hardening may be performed by heating the dam 120 with heat. As described above, when performing the complete hardening of the dam 120, the protective layer 130 may prevent the reaction due to a contact between the temporarily hardened dam 120 and oxygen in the air. Therefore, the protective layer 130 may prevent the dam 120 from being non-hardened due to the reaction of the temporarily hardened dam 120 with oxygen when the complete hardening process of the dam 120 is performed.

According to the method of manufacturing a printed circuit board of the preferred embodiment of the present invention, it is possible to prevent the dam from being non-hardened due to the reaction of the dam with oxygen by the protective layer at the time of forming the dam using the inkjet type.

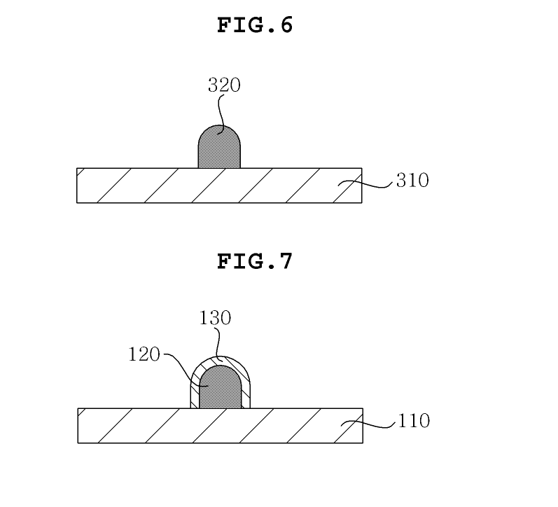

FIG. 6 is a diagram illustrating an existing dam.

Referring to FIG. 6, an existing dam 320 may be formed by an inkjet type. That is, the existing dam 320 may be formed by applying the liquid-phase photo resist on a base substrate 310 and hardening the photo resist.

As described above, the hardness of the dam 320 measured after the existing dam 320 was formed was 18.3 to 23.8%. In this case, as the UV dosage for evaluating the hardness, 600 Mj of i-line 365 nm wavelength was irradiated using a Hg lamp. The reduction in reacting group (C, C═C bonding of acrylate) participating in the hardening was calculated as a ratio to peak intensity of reaction group (C═O bonding) that does not participate in the hardening by using FT-IR as the hardness measuring equipment.

FIG. 7 is a diagram illustrating a dam according to a preferred embodiment of the present invention.

Referring to FIG. 7, the existing dam 120 according to the preferred embodiment of the present invention may be formed by an inkjet type. In the dam 120 according to the preferred embodiment of the present invention, the dam ink that is the liquid-phase photo resist may first be formed on the base substrate 110. Next, the liquid-phase protective layer 130 formed on the dam ink may be formed by being hardened. Here, the protective layer 130 may be formed of PET having excellent oxygen permeable suppression.

The hardness of the dam 120 provided with the protective layer 130 was measured as 87.0% to 88.0%. In this case, as the UV dosage for evaluating the hardness, 600 Mj of i-line 365 nm wavelength was irradiated using a Hg lamp. The reduction in reacting group (C, C═C bonding of acrylate) participating in the hardening was calculated as a ratio to peak intensity of reaction group (C═O bonding) that does not participate in the hardening by using FT-IR as the hardness measuring equipment.

As described above, the hardness of the existing dam (320 of FIG. 6) and the hardness of the dam 120 on which the protective layer 130 according to the preferred embodiment of the present invention was evaluated under the same conditions. As a result, it can be appreciated that the dam 120 on which the protective layer 130 according to the preferred embodiment of the present invention is formed has more excellent hardness than that of the existing dam (320 of FIG. 6).

According to the printed circuit board and the method of manufacturing a printed circuit board of the preferred embodiments of the present invention, it is possible to improve the hardness of the dam even at the time of forming the dam using the inkjet type by forming the protective layer. Further, the dam can be sufficiently hardened even by the inkjet type to form the dam only in the optional area. Therefore, it is possible to save the cost and time according to the formation of the dam.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a base substrate on which a connection pad is formed;
a dam spaced apart from one side of the connection pad; and
a protective layer formed to surround the dam.

2. The printed circuit board as set forth in claim 1, wherein the dam is formed of solder resist.

3. The printed circuit board as set forth in claim 1, wherein the protective layer is formed of liquid-phase thermoplastic resin.

4. The printed circuit board as set forth in claim 1, wherein the protective layer is formed of liquid-phase polyethylene terephthalate.

5. The printed circuit board as set forth in claim 1, wherein at least one connection pad is formed.

6. The printed circuit board as set forth in claim 5, wherein the dams are consecutively formed so as to be spaced apart from each other along one side of at least one connection pad.

7. A method of manufacturing a printed circuit board, comprising:
preparing a base substrate on which a connection pad is formed;
forming temporarily hardened dams spaced apart from one side of the connection pad;
forming a protective layer surrounding the dams; and
hardening the temporarily hardened dams.

8. The method as set forth in claim 7, wherein the forming of the temporarily hardened dam includes:
applying dam ink to a position at which the dam is spaced apart from one side of the connection pad; and
temporarily hardening the dam ink

9. The printed circuit board as set forth in claim 8, wherein the dam ink is a liquid-phase photo resist.

10. The method as set forth in claim 8, wherein the temporarily hardening of the dam ink is performed by irradiating ultraviolet rays to the applied dam ink

11. The method as set forth in claim 7, wherein in the forming of the protective layer, the liquid-phase protective layer is applied to surround the dam.

12. The method as set forth in claim 7, wherein the protective layer is formed of a liquid-phase thermoplastic resin.

13. The method as set forth in claim 7, wherein the protective layer is formed of liquid-phase polyethylene terephthalate.

14. The method as set forth in claim 7, wherein the hardening of the temporarily hardened dams includes:
performing first hardening that irradiates ultraviolet rays to the temporarily hardened dams; and
performing second hardening that heats the dams hardened by ultraviolet rays.
